(19) United States
(12) Patent Application Publication
(10) Pub. No.: US 2019/0214236 A1
(43) Pub. Date: Jul. 11, 2019

(54) TUNABLE ESC FOR RAPID ALTERNATING PROCESS APPLICATIONS

(71) Applicant: Lam Research Corporation, Fremont, CA (US)

(72) Inventors: Dan MAROHL, San Jose, CA (US); David Setton, Danville, CA (US); Craig Rosslee, San Jose, CA (US); Gautam Bhattacharyya, San Ramon, CA (US)

(21) Appl. No.: 15/867,106

(22) Filed: Jan. 10, 2018

(51) Int. Cl. H01J 37/32; H01L 21/67; H01L 21/683

(52) U.S. Cl. CPC H01J 37/32724; H01J 37/32183; H01L 21/67103; H01L 21/67069; H01J 37/3211; H01J 2237/332; H01J 2237/334; H01L 21/6833

(57) ABSTRACT

A substrate support for a substrate processing chamber configured to implement a rapid alternating process includes a baseplate and a heating plate arranged on the baseplate. The heating plate includes a first zone including a first heating element configured to adjust a first temperature of the first zone of the heating plate and a second zone including a second heating element configured to adjust a second temperature of the second zone of the heating plate. A first thermally conductive bond layer is arranged between the heating plate and the baseplate. The first thermally conductive bond layer is configured to transfer heat from the heating plate to the baseplate during the rapid alternating process. The rapid alternating process includes a plurality of alternating deposition steps and etching steps.

### FIELD

The present disclosure relates to moveable edge rings in substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

During manufacturing of substrates such as semiconductor wafers, etch processes and deposition processes may be performed within a processing chamber. The substrate is disposed in the processing chamber on a substrate support such as an electrostatic chuck (ESC) or a pedestal. Process gases are introduced and plasma is struck in the processing chamber.

The processing chamber may include transformer coupled plasma (TCP) reactor coils. A radio frequency (RF) signal, generated by a power source, is supplied to the TCP reactor coils. A dielectric window, constructed of a material such as ceramic, is incorporated into an upper surface of the processing chamber. The dielectric window allows the RF signal to be transmitted from the TCP reactor coils into the interior of the processing chamber. The RF signal excites gas molecules within the processing chamber to generate plasma.

The TCP reactor coils are driven by a transformer coupled capacitive tuning (TCCT) match network. The TCCT match network receives the RF signal supplied by the power source and enables tuning of power provided to the TCP reactor coils. The TCP reactor coils may include an inner coil and an outer coil. The inner coil is disposed within an outer coil. The TCCT match network may include variable capacitors. Each of the variable capacitors may be implemented using a stationary electrode and a movable electrode or using switched capacitors. A ratio of power delivered to the TCP coils can be adjusted during processing by varying capacitance values of the variable capacitors.

### SUMMARY

A substrate support for a substrate processing chamber configured to implement a rapid alternating process includes a baseplate and a heating plate arranged on the baseplate. The heating plate includes a first zone including a first heating element configured to adjust a first temperature of the first zone of the heating plate and a second zone including a second heating element configured to adjust a second temperature of the second zone of the heating plate. A first thermally conductive bond layer is arranged between the heating plate and the baseplate. The first thermally conductive bond layer is configured to transfer heat from the heating plate to the baseplate during the rapid alternating process. The rapid alternating process includes a plurality of alternating deposition steps and etching steps.

In other features, the heating plate corresponds to a ceramic plate of the substrate support, and the ceramic plate is configured to support a substrate arranged on the substrate support during the rapid alternating process.

In other features, the first thermally conductive bond layer has a thickness between 50 and 100 m and a thermal conductivity between 0.5 and 1.0 W/mK.

In other features, the substrate support of claim further includes a ceramic plate arranged on the heating plate. The ceramic plate is configured to support a substrate arranged on the substrate support during the rapid alternating process. A second thermally conductive bond layer is arranged between the ceramic plate and the heating plate.

In other features, a thickness of the first thermally conductive bond layer is greater than a thickness of the second thermally conductive bond layer.

In other features, a thermal conductivity of the first thermally conductive bond layer is less than a thermal conductivity of the second thermally conductive bond layer.

In other features, the first thermally conductive bond layer has a thickness between 200 and 300 μm and a thermal conductivity between 0.1 and 0.6 W/mK.

In other features, the second thermally conductive bond layer has a thickness between 50 and 100 μm and a thermal conductivity between 0.5 and 1.0 W/mK.

In other features, a substrate processing system includes a rapid alternating process substrate processing chamber and further includes the substrate support and a temperature controller configured to control the first heating element and the second heating element to selectively adjust the first temperature and the second temperature, respectively.

In other features, the first zone corresponds to a radial inner zone, the second zone corresponds to a radial outer zone, and the first temperature and the second temperature are different.

In other features, the substrate processing system further includes a transformer coupled capacitive tuning (TCCT) match network configured to drive transformer coupled plasma reactor coils to generate plasma within the substrate processing chamber during the rapid alternating process.

In other features, the substrate processing system further includes a matching circuit configured to bias the substrate support during the rapid alternating process.

In other features, the matching circuit includes at least one of (i) first and second variable capacitors and (ii) first and second switched capacitors.

In other features, the substrate processing system further includes a controller configured to adjust capacitance values of the at least one of the (i) first and second variable capacitors and (ii) first and second switched capacitors.

In other features, to adjust the capacitance values, the controller is configured to switch to a first set of capacitance values during a first portion of a cycle of the rapid alternating process and to a second set of capacitance values during a second portion of the same cycle of the rapid alternating process.

In other features, a duration of each of the plurality of alternating deposition steps and etching steps is less than or equal to one second.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A is a functional block diagram of an example substrate processing system according to the present disclosure;

FIG. 1B is a plan view of an example of inner and outer coils according to the present disclosure;

FIG. 10 is an electrical schematic of an example of a transformer coupled capacitive tuning (TCCT) circuit according to the present disclosure;

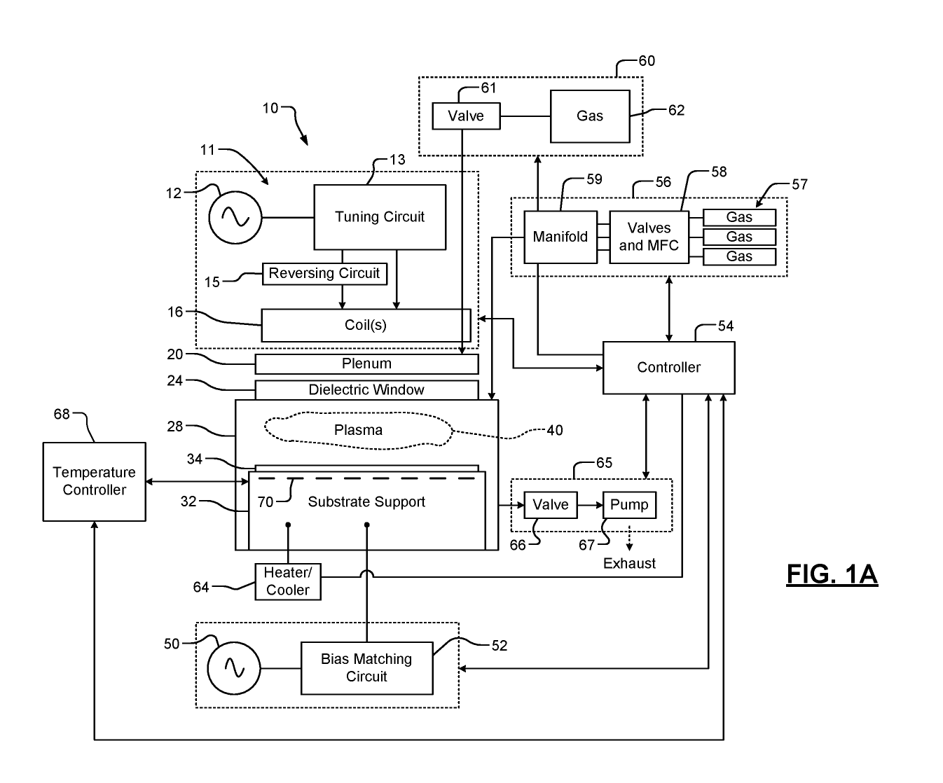

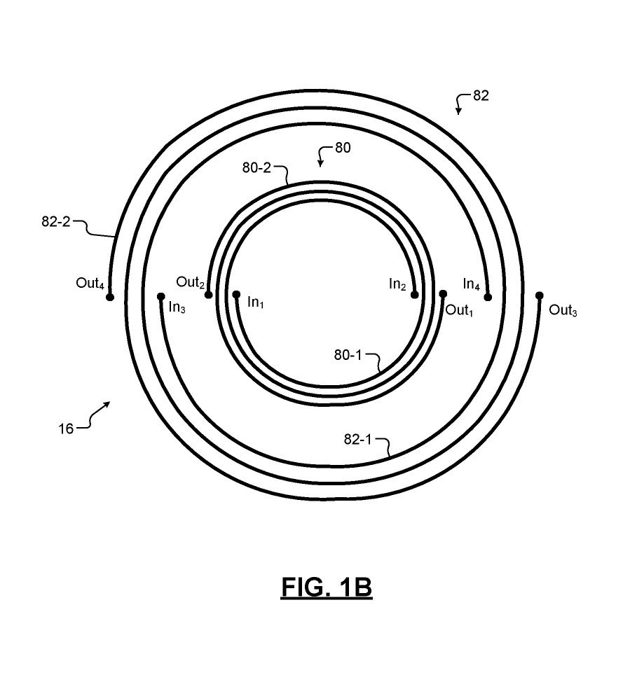

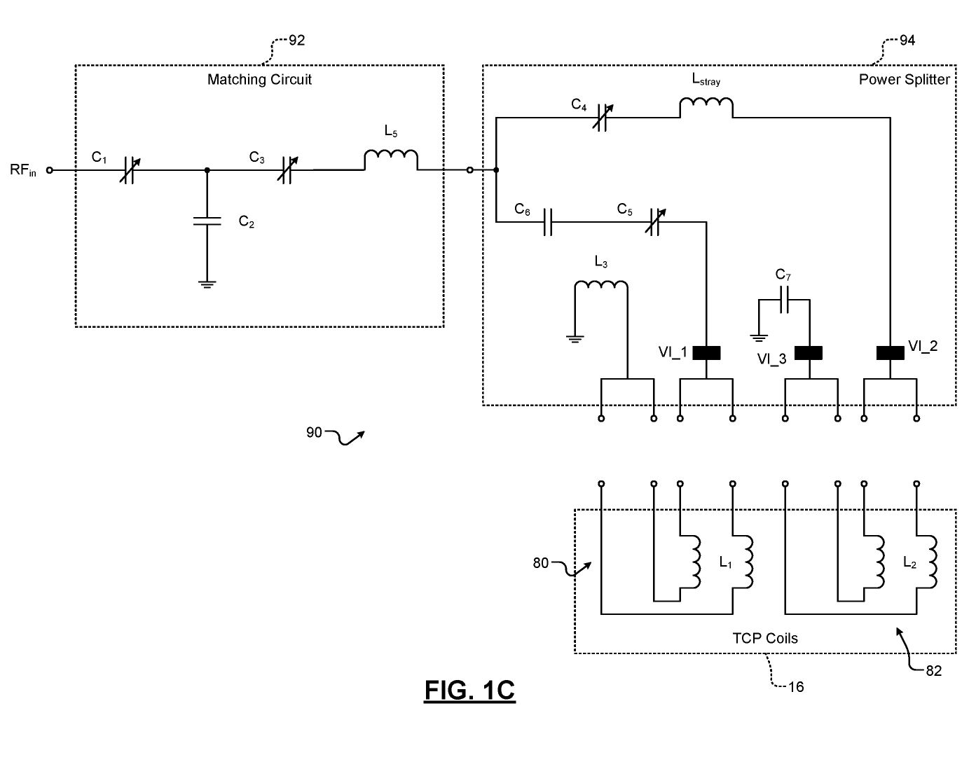

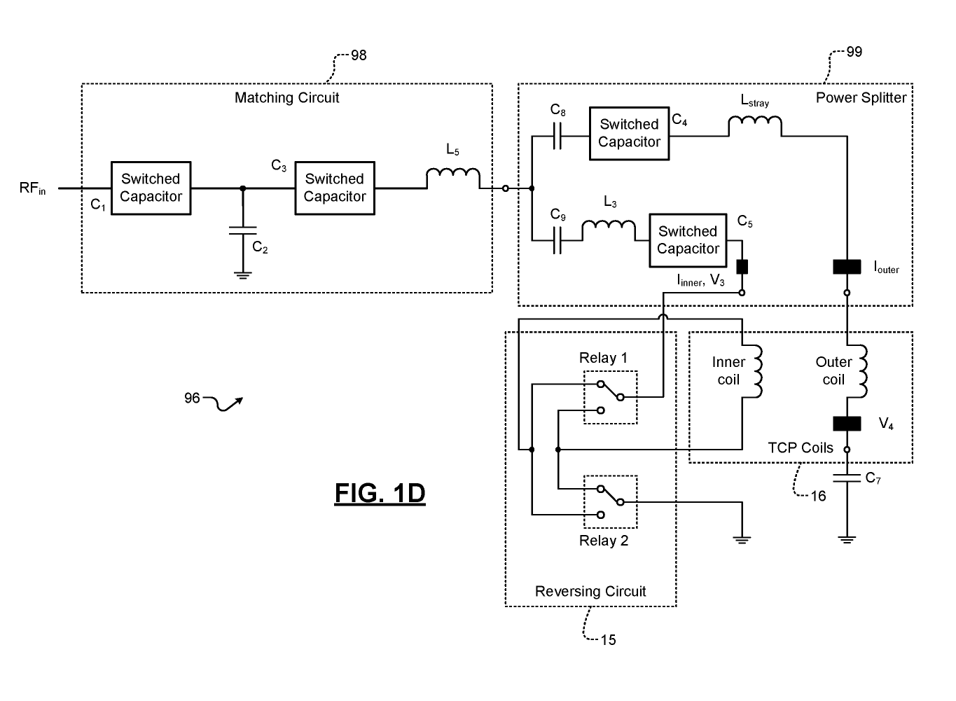

FIG. 1D is an electrical schematic of an example of a TCCT circuit including a switched capacitor circuit according to the present disclosure;

FIG. 2A illustrates zones and macro thermal control elements of an example electrostatic chuck according to the principles of the present disclosure;

FIG. 2B illustrates zones and micro thermal control elements of an example electrostatic chuck according to the principles of the present disclosure;

FIG. 2C is an example electrostatic chuck according to the principles of the present disclosure;

FIG. 2D is another example electrostatic chuck according to the principles of the present disclosure; and

FIG. 3 is an example temperature controller according to the principles of the present disclosure.

In the drawings, reference numbers may be reused to identify similar and/or identical elements.

### DETAILED DESCRIPTION

During processes such as etch, deposition, etc., a substrate is arranged on a substrate support of a substrate processing system. The substrate support may include a ceramic layer arranged to support the substrate. For example, the substrate may be clamped to the ceramic layer during processing.

Some substrate processing systems may be configured to implement a rapid alternating process (RAP), which includes rapidly switching between etch and deposition processes. During a RAP, values of the variable capacitors are varied. In some examples, the duration of each etch process and each deposition process may be 1 second or less. For example, a RAP may be used in microelectromechanical system (MEMS) etching, deep silicon etch (DSiE) processing, etc. An example DSiE process is described in commonly-assigned U.S. patent application Ser. No. 15/671,867, filed on Aug. 8, 2017, which is hereby incorporated by reference in its entirety.

A typical RAP (e.g., a DSiE process) is performed in a processing chamber including a substrate support having a single temperature zone. Accordingly, temperature control of the substrate support may be limited (e.g., using a chiller bath). Some aspects of etch and deposition processing may vary due to characteristics of the substrate processing system, including a temperature of the substrate support. Accordingly, non-uniformities within temperatures across the substrate support may cause process non-uniformities, including, but not limited to, non-uniformities in trench depth, critical dimensions, profile, etc. Characteristics of other system components (e.g., the TCP or TCCT coil characteristics, edge ring characteristics, substrate support liner characteristics, pump location, etc.) may also contribute to radial non-uniformities in etch and deposition processes.

Substrate processing systems and methods according to the principles of the present disclosure implement a temperature-tunable substrate support in a RAP processing chamber. The substrate support may have two or more tunable temperature zones. Accordingly, respective temperatures of different zones of the substrate support may be controlled to compensate for temperature variations and other system and process non-uniformities. For example, in conditions that may cause a decrease in etch rate at some portion of the substrate (e.g., an increase in the etch rate at an edge of the substrate due to edge ring position or profile), a temperature of a corresponding zone (e.g., an outer zone) of the substrate support may be increased to increase etch rate. Conversely, in conditions that may cause an increase in the etch rate, a temperature of the corresponding zone may be decreased to decrease the etch rate.

Temperature-tunable substrate supports in non-RAP implementations typically include a thermally insulative bond layer arranged between a ceramic heating layer and a baseplate of the substrate support. In the non-RAP implementations, the thermally insulative bond layer prevents heat from transferring out of the substrate and/or the ceramic heating layer and into the baseplate. Conversely, some RAP steps may cause significant temperature increases in the substrate, and the substrate temperature may increase to a temperature that is unsuitable for a subsequent RAP deposition step. Accordingly, the substrate support according to the principles of the present disclosure includes one or more thermally conductive bond layers configured to maximize the conduction of heat from the ceramic heating plate.

Referring now to FIG. 1A, an example of a substrate processing system 10 according to the present disclosure is shown. The substrate processing system 10 includes a coil driving circuit 11. In some examples, the coil driving circuit 11 includes an RF source 12 and a tuning circuit 13. The tuning circuit 13 may be directly connected to one or more inductive TCP coils 16. Alternatively, the tuning circuits 13 may be connected by an optional reversing circuit 15 to one or more of the coils 16. The tuning circuit 13 tunes an output of the RF source 12 to a desired frequency and/or a desired phase, matches an impedance of the coils 16 and splits power between the TCP coils 16. The reversing circuit 15 is used to selectively switch the polarity of current through one or more of the TCP coils 16.

In some examples, a plenum 20 may be arranged between the TCP coils 16 and a dielectric window 24 to control the temperature of the dielectric window with hot and/or cold air flow. The dielectric window 24 is arranged along one side of a processing chamber 28. The processing chamber 28 further comprises a substrate support (or pedestal) 32. The substrate support 32 may include an electrostatic chuck (ESC), or a mechanical chuck or other type of chuck. Process gas is supplied to the processing chamber 28 and plasma 40 is generated inside of the processing chamber 28. The plasma 40 etches an exposed surface of the substrate 34. An RF source 50 and a bias matching circuit 52 may be used to bias the substrate support 32 during operation to control ion energy.

A gas delivery system 56 may be used to supply a process gas mixture to the processing chamber 28. The gas delivery system 56 may include process and inert gas sources 57, a gas metering system 58 such as valves and mass flow controllers, and a manifold 59. A gas delivery system 60 may be used to deliver gas 62 via a valve 61 to the plenum 20. The gas may include cooling gas (air) that is used to cool the TCP coils 16 and the dielectric window 24. A heater/cooler 64 may be used to heat/cool the substrate support 32 to a predetermined temperature. An exhaust system 65 includes a valve 66 and pump 67 to remove reactants from the processing chamber 28 by purging or evacuation.

A controller 54 may be used to control the etching process. The controller 54 monitors system parameters and controls delivery of the gas mixture, striking, maintaining and extinguishing the plasma, removal of reactants, supply of cooling gas, and so on. Additionally, as described below in detail, the controller 54 may control various aspects of the coil driving circuit 11, the RF source 50, and the bias matching circuit 52, etc. For example, processing chambers using a TCCT match network with switched capacitors are shown and described in commonly-assigned U.S. Pat. No. 9,515,633, which is hereby incorporated by reference in its entirety.

The substrate support 32 according to the principles of the present disclosure is temperature-tunable. In one example, a temperature controller 68 may be connected to a plurality of heating elements 70, such as thermal control elements (TCEs), arranged in the substrate support 32. The heating elements 70 may include, but are not limited to, macro heating elements corresponding to respective zones in a multi-zone heating plate and/or an array of micro heating elements disposed across multiple zones of a multi-zone heating plate. The temperature controller 68 may be used to control the plurality of heating elements 70 to control a temperature of the substrate support 32 and the substrate 34 as described below in more detail.

Referring now to FIG. 1B, an example of the TCP coils 16 is shown. While a specific coil configuration is shown in FIG. 1B, other coil arrangements may be used. The TCP coils 16 may include an inner coil 80 and an outer coil 82. The inner coil 80 includes a first conductor 80-1 having an input end In, and an output end Out, and a second conductor 80-2 having an input end Inₜ and an output end Out₂. The first conductor 80-1 and the second conductor 80-2 are wound in a generally circular or looped path adjacent to each other. The outer coil 82 includes a first conductor 82-1 having an input end Inₐ and an output end Out₃ and a second conductor 82-2 having an input end Inₐ and an output end Out₄. The first conductor 82-1 and the second conductor 82-2 are wound in a generally circular or looped path adjacent to each other.

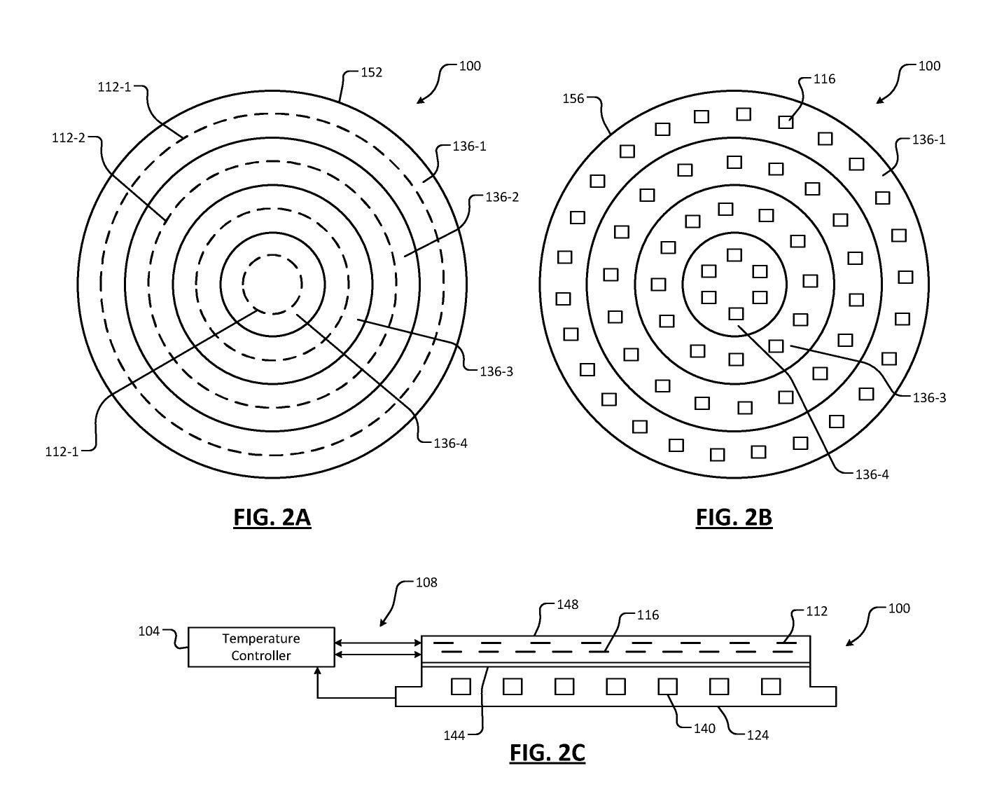

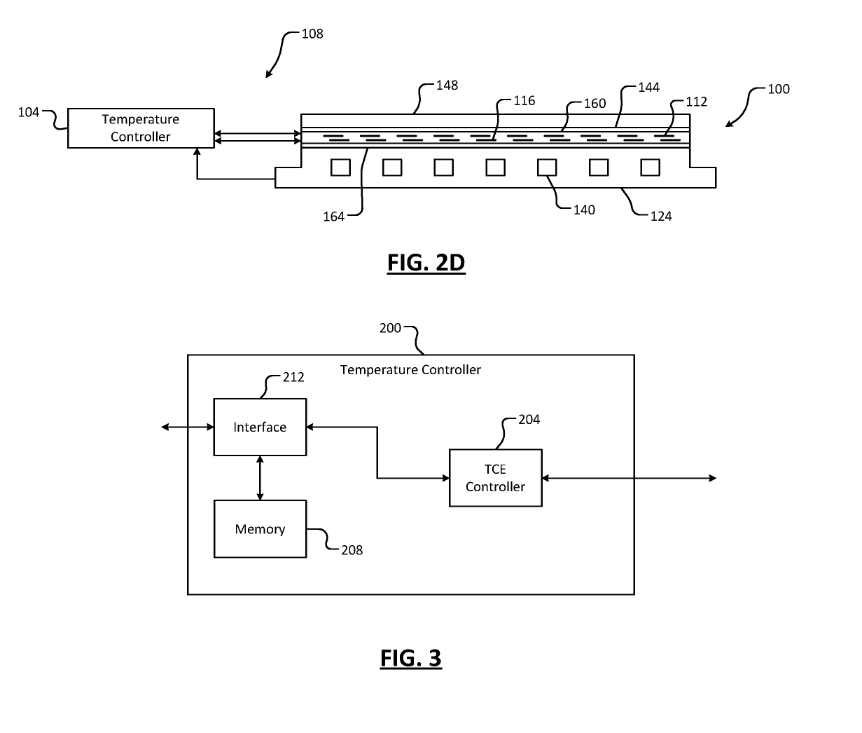

Referring now to FIG. 10, an example of a TCCT circuit 90 includes a matching circuit 92 and a power splitter 94 that drive the TCP coils 16. The matching circuit 92 receives an RF input signal RF_{IN} from the RF source 12. The matching circuit 92 includes a plurality of capacitors C₁, C₂, and C₃, and an inductor L₅. The RF input signal RF_{IN} is received at a first terminal of the capacitor C₁. A second terminal of the capacitor C₁ is connected to first terminals of the capacitors C₂ and C₃. A second terminal of the capacitor C₃ is connected to a first terminal of the inductor L₅.

In some examples, the capacitors C₁ and C₃ are variable capacitors having capacitance values that are adjusted to match an impedance of the coils (and the plasma). In some examples, the capacitors C₁ and C₃ are switched capacitor circuits including two or more capacitors and at least one switch. In some examples, the capacitors C₁ and C₃ include motor-controlled vacuum capacitors with a stationary electrode and a movable electrode. The matching circuit 92 matches the impedance of the RF source 12 to the impedance of the TCP coils 16. Values of the variable capacitors C₁ and C₃ are varied to match the impedance of the TCP coils 16 during operation as will be described further below. The output of the matching circuit 92 is connected to the power splitter 94.

The power splitter 94 is coupled to the inner and outer coils 80, 82 (i.e., the TCP coils 16) as shown. The power splitter 94 supplies the RF power received from the matching circuit 92 to the inner and outer coils 80, 82. The power splitter 94 includes a plurality of capacitors C₄, C₅, C₆, C₇, and inductors L_{stray} (of strap) and L₃. A second terminal of the inductor L₅ is connected to first terminals of the capacitors C₄ and C₆. A second terminal of the capacitor C₄ is connected to first ends of the coil L₂ via the strap (having stray inductance L_{stray}). Second ends of the coil L₂ are connected to a capacitor C₇. A second terminal of the capacitor C₆ is connected to a first terminal of the capacitor C₅. A second terminal of the capacitor C₅ is connected to first ends of the coil L₁. Second ends of the coil L₁ are connected to the inductor

L₃.

In some examples, the capacitors C₄ and C₅ are variable capacitors. In some examples, the variable capacitors C₄ and C₅ are switched capacitor circuits including two or more capacitors and at least one switch. In some examples, the capacitors C₄ and C₅ include motor-controlled vacuum capacitors. Values of the capacitors C₄ and C₅ may be varied in conjunction with (or independently from) the values of the variable capacitors C₁ and C₃.

Referring now to FIG. 1 D, a TCCT circuit 96 includes a matching circuit 98. The matching circuit 98 includes a switched capacitor circuit C₁ having a first terminal receiving an RF input signal RF_{IN}. The switched capacitor circuit C₁ includes a second terminal connected to a first terminal of a capacitor C₂ and a first terminal of a switched capacitor circuit C₃. In some examples, the switched capacitor circuits C₁ and C₃ include two or more capacitors and at least one switch. A second terminal of the switched capacitor circuit C₃ is connected to a first terminal of an inductor L₅.

The second terminal of the inductor L₅ is connected to a power splitter 99. More particularly, the second terminal of the inductor L₅ is connected to first terminals of capacitors C₈ and C₉. A second terminal of the capacitor C₈ is connected to a first terminal of a variable capacitor C₄, which can be a switched capacitor circuit. A second terminal of the variable capacitor C₄ is connected by the strap (having stray inductance L_{stray}) to a first terminal of the outer coil. A second terminal of the outer coil is connected by a capacitor C₇ to a reference potential such as ground.

The second terminal of the capacitor C₉ is connected to a first terminal of an inductor L₃. A second terminal of the inductor L₃ is connected to a first terminal of a variable capacitor C₅, which can also be a switched capacitor circuit. A second terminal of the variable capacitor C₅ is connected by the reversing circuit 15 to the inner coil, which can also be a switched capacitor circuit.

Referring now to FIGS. 2A, 2B, 2C, and 2D, an example substrate support (such as an electrostatic chuck, or ESC) 100 is shown. A temperature controller 104 communicates with the substrate support 100 via one or more electrical or communication connections 108. For example, the electrical connections 108 may include connections for providing voltage/power to control macro TCEs 112-1, 112-2, 112-3, and 112-4, referred to collectively as macro TCEs 112. In some examples, the substrate support 100 may further include micro TCEs 116. The connections 108 may further include connections for receiving feedback, such as temperature feedback from a baseplate 124 (for example only, from a baseplate sensor), measurements of voltage and/or current provided to the micro TCEs 116, etc. Although the micro TCEs 116 as shown in FIGS. 2A and 2B are aligned with the macro TCEs 112 in a circular, concentric arrangement, other arrangements of the micro TCEs 116 with respect to the macro TCEs 112 may be used.

As shown, the substrate support 100 is a multi-zone ESC including zones 136-1, 136-2, 136-3, and 136-4, referred to collectively as zones 136. Although shown with the four concentric zones 136, in embodiments the substrate support 100 may include two, three, or more than four of the zones 136. The shapes of the zones 136 may vary. For example, the zones 136 may be provides as quadrants or another grid-like arrangement. Each of the zones 136 includes, for example only, a respective one of the macro TCEs 112. Further, although the substrate support 100 is shown to include the micro TCEs 116, in other examples the substrate support 100 includes only the macro TCEs 112 in two or more of the zones 136 and does not include the micro TCEs 116. The baseplate 128 may further include coolant channels 140, a thermally conductive bond layer 144 formed on the baseplate 124, and a multi-zone ceramic plate 148 formed on the bond layer 144.

As shown in FIG. 2C, the ceramic plate 148 may include multiple bonded layers, including a first layer 152 as shown in FIG. 2A and a second layer 156 as shown in FIG. 2B. The first layer 152 includes the macro TCEs 112 and the second layer 256 includes the plurality of micro TCEs 116. In other words, in some examples, the ceramic plate 148 may correspond to a heating plate including integrated heating elements.

Conversely, as shown in FIG. 2D, the substrate support 100 includes the ceramic plate 148 and a separate heating plate 160 including one or more bonded layers of heating elements such as the macro TCEs 112 and the micro TCEs 116. In this example, the substrate support 100 may include the thermally conductive bond layer 144 arranged between the heating plate 160 and the ceramic plate 148 and a second thermally conductive bond layer 164 arranged between the heating plate 160 and the baseplate 124.

The temperature controller 104 controls the macro TCEs 112 and the micro TCEs 116 according to a desired setpoint temperature. For example, the temperature controller 104 may receive (e.g., from the controller 54 as shown in FIG. 1A) a setpoint temperature for one or more of the zones 136. For example only, the temperature controller 104 may receive a same setpoint temperature for all or some of the zones 136 and/or different respective setpoint temperatures for each of the zones 136. The setpoint temperatures for each of the zones 136 may vary across different processes and different steps of each process.

The temperature controller 104 controls the macro TCEs 112 for each of the zones 136 based on the respective setpoint temperatures and temperature feedback. For example, the temperature controller 104 individually adjusts power (e.g., current) provided to each of the macro TCEs 112 to achieve the setpoint temperatures. The macro TCEs 112 may each include a single resistive coil or other structure schematically represented by the dashed lines of FIG. 2A. Accordingly, adjusting one of the macro TCEs 112 affects the temperature of the entire respective zone 136, and may also affect other ones of the zones 136.

Conversely, the temperature controller 104 may individually control each of the micro TCEs 116 to locally adjust temperatures of the zones 136. For example, although each micro TCE 116 may be located entirely within one of the zones 136, adjusting a thermal output of any one of the micro TCEs 116 may have a thermal impact across multiple zones 136 and localities of the ceramic plate 148. Accordingly, one or more of the micro TCEs 116 may be selectively activated and/or deactivated to further adjust temperatures of the zones 136. The temperature controller 104 implements the systems and methods according to the present disclosure to control the temperature of the substrate support 100 as described below in more detail.

The thermally conductive bond layers 144 and/or 164 are configured to transfer heat from a substrate (e.g., the substrate 22 as shown in FIG. 1) arranged on the ceramic plate 148 to the baseplate 124. For example, the RAP may include alternating break-through, etch, and deposition steps having a relatively short duration (e.g., 0.5 seconds) as compared to non-RAP implementations. Some steps, such as silicon etch steps, are highly exothermic and cause a temperature of the substrate to increase sharply. Conversely, some steps, such as deposition steps, may require a relatively low temperature (i.e., as compared to the temperature of the substrate reached during a previous silicon etch step) to achieve a desired polymer thickness and/or density. Accordingly, the bond layers 144/164 according to the principles of the present disclosure are configured to compensate for different relative temperatures desired for each RAP step while also accommodating temperature control of the ceramic heating plate.

For example, temperature-tunable substrate supports in non-RAP implementations include a thermally insulative bond layer arranged between the ceramic heating layer and the baseplate of the substrate support. In the non-RAP implementations, the thermally insulative bond layer prevents heat from transferring out of the substrate and/or the ceramic heating layer and into the baseplate, and from transferring between different regions (e.g., zones) of the heating layer and the substrate via the bond layer and the baseplate. Accordingly, larger temperature differences between different zones of the heating layer and substrate can be maintained while process steps are performed at greater temperatures (e.g., 60 to 80° C. within the processing chamber).

Conversely, while the RAP chamber (e.g., the processing chamber 28) may be operated at a much lower temperature during the RAP (e.g., −10 to 15° C.) relative to non-RAP implementations, some steps of the RAP may cause significant, undesired temperature increases as described above, and the substrate may increase to a temperature that is unsuitable for a subsequent RAP deposition step. Accordingly, increasing the temperature of the substrate using a temperature-tunable substrate support including a thermally insulative bond layer would further interfere with RAP deposition steps, precluding the use of such a substrate support in a RAP environment.

Consequently, the thermally conductive bond layers 144/164 are configured to maximize the conduction of heat from the ceramic plate 148 (and the substrate arranged thereon) and into the baseplate 124 while maintaining a temperature difference of up to approximately 10° C. (e.g., +/−1° C.) between adjacent ones of the zones 136. In this manner, the temperature-tunable substrate support 100 including the thermally conductive bond layers 144/164 provide temperature tunability of the substrate during the RAP while also maintaining lower temperatures suitable for RAP deposition steps. For example, the bond layer 144 may have a thickness of approximately 75 μm (e.g., 50-100 μm) and a thermal conductivity of approximately 0.83 W/mK (e.g., 0.5-1.0 W/mK). The bond layer 164 may have a thickness of approximately 250 μm (e.g., 200-300 μm) and a thermal conductivity between 0.1 W/mK and 0.6 W/mK.

Referring now to FIG. 3, an example temperature controller 200 according to the principles of the present disclosure includes a TCE controller 204, memory 208, and an interface 212 (for communicating with, for example, the controller 54 as shown in FIG. 1A, for receiving user inputs, etc.). For example only, the memory 208 may include non-volatile memory such as flash memory. The temperature controller 200 receives process setpoint temperatures (e.g., desired setpoint temperatures for a RAP, respective setpoint temperatures for respective periods and/or process steps of the RAP, etc.) and/or other parameters from the controller 54 via the interface 212. The interface 212 provides the process setpoint temperatures to the TCE controller 204. The process setpoint temperatures may include a single setpoint temperature for every zone 136 and/or different process setpoint temperatures for each of the respective zones 136. In some examples, the process setpoint temperatures include first setpoint temperatures for a first period of the RAP, second setpoint temperatures for a second period of the RAP, etc. The TCE controller 204 controls the macro TCEs 112 according to the received process setpoint or setpoints. In examples that include the micro TCEs 116, the TCE controller 204 may also control the micro TCEs 116 to achieve desired process setpoint temperatures throughout each of the zones 136 to compensate for temperature non-uniformities within the zones 136.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system.

The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate support for a substrate processing chamber configured to implement a rapid alternating process, the substrate support comprising:
a baseplate;
a heating plate arranged on the baseplate, wherein the heating plate comprises
a first zone including a first heating element configured to adjust a first temperature of the first zone of the heating plate, and
a second zone including a second heating element configured to adjust a second temperature of the second zone of the heating plate; and
a first thermally conductive bond layer arranged between the heating plate and the baseplate, wherein the first thermally conductive bond layer is configured to transfer heat from the heating plate to the baseplate during the rapid alternating process, and wherein the rapid alternating process includes a plurality of alternating deposition steps and etching steps.

2. The substrate support of claim 1, wherein the heating plate corresponds to a ceramic plate of the substrate support, wherein the ceramic plate is configured to support a substrate arranged on the substrate support during the rapid alternating process.

3. The substrate support of claim 2, wherein the first thermally conductive bond layer has a thickness between 50 and 100 μm and a thermal conductivity between 0.5 and 1.0 W/mK.

4. The substrate support of claim 1, further comprising:
a ceramic plate arranged on the heating plate, wherein the ceramic plate is configured to support a substrate arranged on the substrate support during the rapid alternating process; and
a second thermally conductive bond layer arranged between the ceramic plate and the heating plate.

5. The substrate support of claim 4, wherein a thickness of the first thermally conductive bond layer is greater than a thickness of the second thermally conductive bond layer.

6. The substrate support of claim 5, wherein a thermal conductivity of the first thermally conductive bond layer is less than a thermal conductivity of the second thermally conductive bond layer.

7. The substrate support of claim 4, wherein the first thermally conductive bond layer has a thickness between 200 and 300 μm and a thermal conductivity between 0.1 and 0.6 W/mK.

8. The substrate support of claim 5, wherein the second thermally conductive bond layer has a thickness between 50 and 100 μm and a thermal conductivity between 0.5 and 1.0 W/mK.

9. A substrate processing system including a rapid alternating process substrate processing chamber and further comprising:
the substrate support of claim 1; and
a temperature controller configured to control the first heating element and the second heating element to selectively adjust the first temperature and the second temperature, respectively.

10. The substrate processing system of claim 9, wherein the first zone corresponds to a radial inner zone, the second zone corresponds to a radial outer zone, and the first temperature and the second temperature are different.

11. The substrate processing system of claim 9, further comprising a transformer coupled capacitive tuning (TCCT) match network configured to drive transformer coupled plasma reactor coils to generate plasma within the substrate processing chamber during the rapid alternating process.

12. The substrate processing system of claim 11, further comprising a matching circuit configured to bias the substrate support during the rapid alternating process.

13. The substrate processing system of claim 12, wherein the matching circuit includes at least one of (i) first and second variable capacitors and (ii) first and second switched capacitors.

14. The substrate processing system of claim 13, further comprising a controller configured to adjust capacitance values of the at least one of the (i) first and second variable capacitors and (ii) first and second switched capacitors.

15. The substrate processing system of claim 14, wherein, to adjust the capacitance values, the controller is configured to switch to a first set of capacitance values during a first portion of a cycle of the rapid alternating process and to a second set of capacitance values during a second portion of the same cycle of the rapid alternating process.

16. The substrate support of claim 1, wherein a duration of each of the plurality of alternating deposition steps and etching steps is less than or equal to one second.
